(19) United States
(12) Patent Application Publication
(10) Pub. No.: US 2013/0107153 A1
(43) Pub. Date: May 2, 2013

(54) THIN FILM TRANSISTOR ARRAY STRUCTURE AND LIQUID CRYSTAL PANEL USING THE SAME

(71) Applicant: Shijian Qin, Shenzhen (CN)

(72) Inventor: Shijian Qin, Shenzhen (CN)

(73) Assignee: Shenzhen China Star Optoelectronics Technology Co., Ltd., Shenzhen (CN)

(21) Appl. No.: 13/378,122

(22) PCT Filed: Nov. 7, 2011
(86) PCT No.: PCT/CN11/81869

§ 371 Date: Dec. 14, 2011

(30) Foreign Application Priority Data
Oct. 27, 2011 (CN) 201110331872.2

(51) Int. Cl. H01L 33/08; G02F 1/136

(52) U.S. Cl. 349/43; 257/59; 257/72; 257/E33.012

(57) ABSTRACT

The present disclosure provides a TFT array substrate. The TFT array substrate includes a plurality of data lines, a plurality of gate lines, a plurality of pixel areas defined by the data lines and the scan lines, a pixel electrode disposed in each pixel area, a storage capacitor disposed on each gate line; and a TFT disposed on the junction of the data line and the gate line. The present disclosure further provides a liquid crystal panel with the TFT array substrate. In the present disclosure, TFTs are respectively disposed on the junctions of the data lines and the gate lines to increase an aperture ratio of a LCD without reducing the number of wirings of the gate lines and data lines. Additionally, the storage capacitor and the compensation capacitor are disposed on the gate line so as to further increase the aperture ratio.

### BACKGROUND

1. Technical Field

The present disclosure relates to liquid crystal displaying technologies, and particularly to a liquid crystal panel and a thin film transistor array substrate thereof.

2. Description of Related Art

Thin film transistors (TFTs) play important roles in the tablet displaying technologies due to their small sizes, low power consumption, and non-radiation. A TFT liquid crystal display (LCD) often includes a TFT array substrate, a color filter array substrate, and a liquid crystal layer disposed between the TFT array substrate and the color filter array substrate.

The TFT array substrate is used as a driving circuit substrate for driving the liquid crystal layer. The TFT array substrate includes a plurality of gate lines and a plurality of data lines respectively perpendicular to the gate lines, and the gate lines insulatingly intersect the data lines for defining a plurality of pixel areas. The TFT array substrate further includes a TFT, a pixel electrode, and a storage capacitor disposed in each pixel area. The TFT often includes a gate electrode connected to the corresponding gate line, a source electrode connected to the corresponding data line, and a drain electrode connected to the pixel electrode. When the gate lines are driven, each TFT is turned on to allow a gray scale voltage signal to be applied to the pixel electrode thereof through the corresponding data line. Thus, electric field can be generated by the corresponding pixel electrode to rotate liquid crystal molecules in the liquid crystal layer to change the orientation; therefore, the TFT liquid crystal display displays different images.

In the above-described TFT array substrate, how to improve the aperture ratio which is the ratio between an area of an optical transmission portion and an optical block portion is troubling people for a long time. In a pixel area, the optical block portion includes the TFT, the gate lines, the data lines, the storage capacitor, and material of black matrix. Generally, wirings of the gate lines and the data lines are reduced for increasing the aperture ratio. However, in this situation, resistances of the gate lines and the data lines are increased obviously, and RC delay of the TFT array substrate is also increased simultaneously.

### SUMMARY

The present disclosure provides a thin film transistor (TFT) array substrate to increase the aperture ratio of a liquid crystal display in case of keeping the number of data lines and scan lines unchanged.

The TFT array substrate includes a plurality of data lines, a plurality of gate lines insulatingly intersecting with the data lines respectively, a plurality of pixel areas defined by the data lines and scan lines. Each pixel area includes: a pixel electrode disposed in each pixel area; a storage capacitor disposed on each gate line; a thin film transistor disposed on the junction of the data line and the gate line and width of a part of each gate line corresponding to the thin film transistor being larger than that of the other part thereof. Each TFT includes a gate electrode connected to the gate line, a source electrode connected to the corresponding data line, a drain electrode connected to the corresponding pixel electrode; and a first conductive channel and a second conductive channel formed between the source electrode and the drain electrode. Widthwise directions of the first conductive channel and the second conductive channel are respectively parallel to the corresponding data line and gate line, and the second conductive channel communicates with the first conductive channel to define an L shape.

The present disclosure further provides another TFT array substrate. The TFT array substrate includes a plurality of data lines; a plurality of gate lines insulatingly intersecting with the data lines respectively, a plurality of pixel areas defined by the data lines and scan lines. Each pixel area includes: a pixel electrode disposed in each pixel area; a storage capacitor disposed on each gate line; a thin film transistor disposed on the junction of the data line and the gate line.

Preferably, the pixel area further comprises a compensation capacitor disposed on each gate line for compensating a parasitic capacitance generated on the junction of the data line and the gate line.

Preferably, the compensation capacitor and the storage capacitor are disposed on the corresponding gate line between two adjacent TFTs.

Preferably, each TFT includes a gate electrode connected to the corresponding gate line, a source electrode connected to the corresponding data line, and a drain electrode connected to the pixel electrode, a conductive channel is formed between the source electrode and the drain electrode with a widthwise direction thereof parallel to the corresponding data line.

Preferably, width of a part of each gate line of each pixel area corresponding to the at least one TFT is larger than that of the other part thereof.

Preferably, each TFT includes a gate electrode connected to the corresponding gate line, a source electrode connected to the corresponding data line, and a drain electrode connected to the pixel electrode, a first conductive channel and a second conductive channel are formed between the source electrode and the drain electrode, widthwise directions of the first conductive channel and the second conductive channel are respectively parallel to the corresponding data line and the corresponding gate line, and the second conductive channel communicates with the first conductive channel to define an L shape.

The present disclosure further yet provides a liquid crystal panel. The liquid crystal panel includes a TFT array substrate. The TFT array substrate includes a plurality of data lines, a plurality of the gate lines insulatingly intersecting with the data lines respectively; a plurality of pixel areas defined by the data lines and scan lines. Each pixel area includes: a pixel electrode disposed in each pixel area; a storage capacitor disposed on each gate line; a thin film transistor disposed on the junction of the data line and the gate line.

In the TFT array substrate of the liquid crystal panel of the present disclosure, the TFTs are respectively disposed on the junctions of the data lines and the gate lines to increase the aperture ratio of the TFT array substrate without reducing the number of the wirings of the gate lines and the data lines. Additionally, the storage capacitor is disposed on the gate line, thus, the aperture ratio can be further increased.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a schematic view of a thin film transistor (TFT) array substrate in accordance with a first embodiment of the present disclosure.

FIG. 2 is an enlarged view of a TFT of FIG. 1.

FIG. 3 is a schematic view of a TFT array substrate in accordance with a second embodiment of the present disclosure.

FIG. 4 is a schematic view of a TFT array substrate in accordance with a third embodiment of the present disclosure.

FIG. 5 is an en enlarged view of a TFT of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

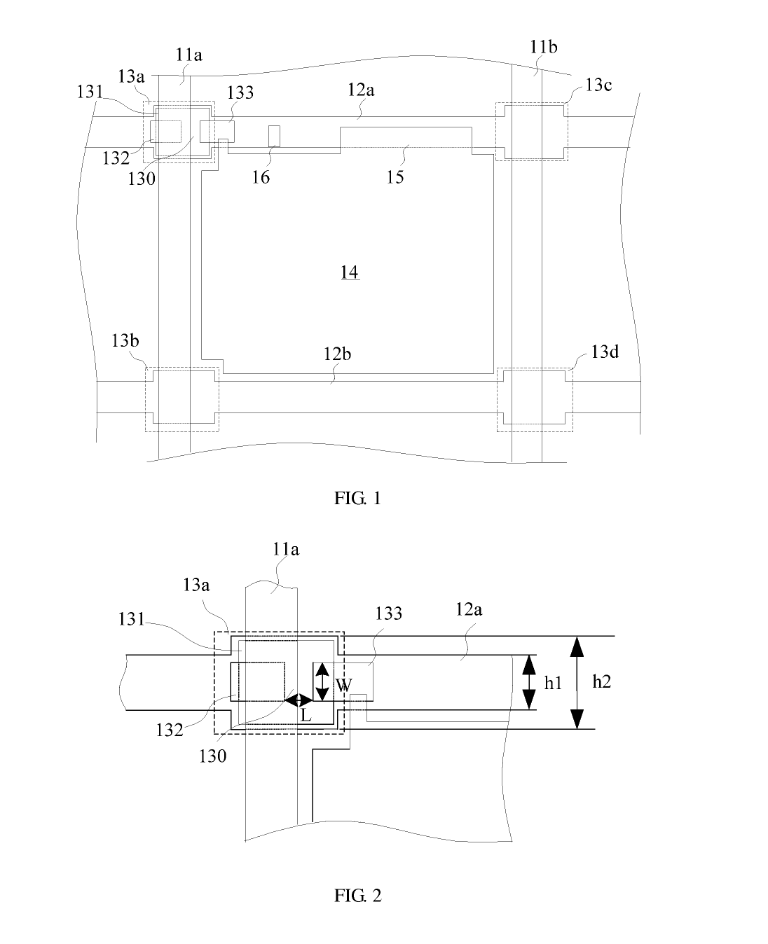

Referring to FIGS. 1 and 2, FIG. 1 is a schematic view of a thin film transistor (TFT) array substrate in accordance with a first embodiment of the present disclosure; FIG. 2 is an enlarged view of a TFT of FIG. 1. The TFT array substrate includes a plurality of parallel data lines and a plurality of parallel gate lines. The data lines perpendicularly and insulatively intercross the gate lines. Every two adjacent data lines intercrossing every two adjacent gate lines define a pixel area. For example, as shown in FIG. 1, the TFT array substrate includes two adjacent data lines 11a, 11b and two adjacent gate lines 12a, 12b which intercross the data lines 11a, 11b to define a pixel area in which a pixel electrode is disposed.

Four thin film transistors 13a, 13b, 13c, and 13d are respectively disposed in four junctions where the two data lines 11a, 11b insulatingly intercross the two gate lines 12a, 12b. Take the TFT 13a as an example, the TFT 13a used as a switching unit of the pixel electrode 14 connects the pixel electrode 14, the TFT 13a includes a gate electrode 131 connected to the gate line 12a, a source electrode 132 connected to the data line 11a, and a drain electrode 133 connected to the pixel electrode 14. The gate electrode 131 is used as switch of the TFT 13a. A conductive channel 130 is formed between the drain electrode 133 and the source electrode 132, and the long side of the conductive channel 130 is parallel to the extended direction of the data line 11a.

In operation, a scanning driver sequentially outputs a plurality of scanning signals to each gate line so as to turn on the TFTs respectively connected the gate lines. For example, when the scanning signal is applied to the gate line 12a, the TFT 13a is turned on. At the same time, a data driver outputs a gray scale voltage signal to the source electrode 132 of the TFT 13a via the data line 11a. The gray scale voltage then is applied to the pixel electrode 14 through the drain electrode 133 of the TFT 13a. Thus, electric field is generated by the pixel electrode 14 to rotate liquid crystal molecules in the liquid crystal layer to change the orientation; therefore, the TFT liquid crystal display displays different images.

The pixel electrode 14 is partly overlapped with the gate line 12a to define a storage capacitor 15. A compensation capacitor 16 is disposed on the gate line 12a to compensate a parasitic capacitance generated by overlapping between the data line 11a and the gate line 12a. When the TFT 13a is turned on, the storage capacitor 15 is charged into certain voltage, and keeps the gray scale voltage of the pixel electrode 14 unchanged when the TFT 13a is turned off. In this situation, the gray scale voltage applied to the pixel electrode 14 can be kept unchanged until the TFT 13a is turned on again, therefore, the liquid crystal display can continuously display the images. In the process of fabricating TFT substrate, the value of the parasitic capacitance may be changed in different TFT array substrates due to different tolerances. In this state, the compensation capacitor 16 can compensate the parasitic capacitance to allow the total capacitance value of the storage capacitor 15 and the compensation capacitor 16 to reach a stable value. Thus, the compensation capacitor 16 can improve the electrical characteristics of the TFT 13a. Additionally, since the storage capacitor 15 and the compensation capacitor 16 are all disposed on the gate line 12a, therefore, an aperture ratio of the TFT substrate is increased.

In the present disclosure, the TFT 13a is disposed on the junction the data line 11a intersects the gate line 12a, thus, the aperture ratio of the pixel electrode 14 can be increased in case of keeping wirings of the gate line 12a and the data line 11a unchanged. Additionally, the storage capacitor 15 and the compensation capacitor 16 are all disposed on the gate line 12a so as to increase the aperture ratio.

Referring to FIG. 2, in a situation where the conductive channel 130 has a width W and has a length L, a width/length ratio of the conductive channel 130 can be expressed as W/L. According to the electrical characteristics of the TFT 13a, a charging current of the TFT 13a is proportional to width/length ratio W/L. In this state, in order to increase the charging current of the TFT 13a, the width W of the conductive channel 130 needed to be increased. Therefore, a part of the gate line 12a corresponding to the TFT 13a needs to be widened from h1 to h2 to allow the TFT 13a with the increased width W to be disposed on the data line 11a. That is, a width of the part of the gate line 12a corresponding to the TFT 13a is larger than that of the other part of the gate line 12a.

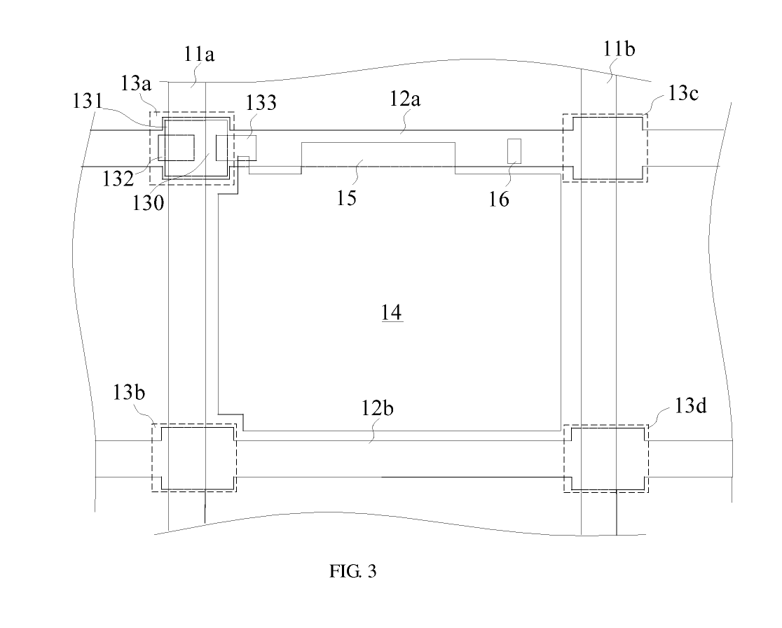

Referring to FIG. 3, in a second embodiment of this invention, the position of the compensation capacitor 16 is different from that of the first embodiment. Take the compensation capacitor 16 corresponding to the TFT 13a as an example, in the first embodiment, the compensation capacitor 16 is disposed between the TFT 13a and the TFT 13c, and is adjacent to the TFT 13a. While in the second embodiment, the compensation capacitor 16 is adjacent to the TFT 13c. It is noted that in other embodiments, the position of the compensation capacitor 16 can be further adjusted only if the total capacitance value of the parasitic capacitance and the compensation capacitor 16 remains unchanged.

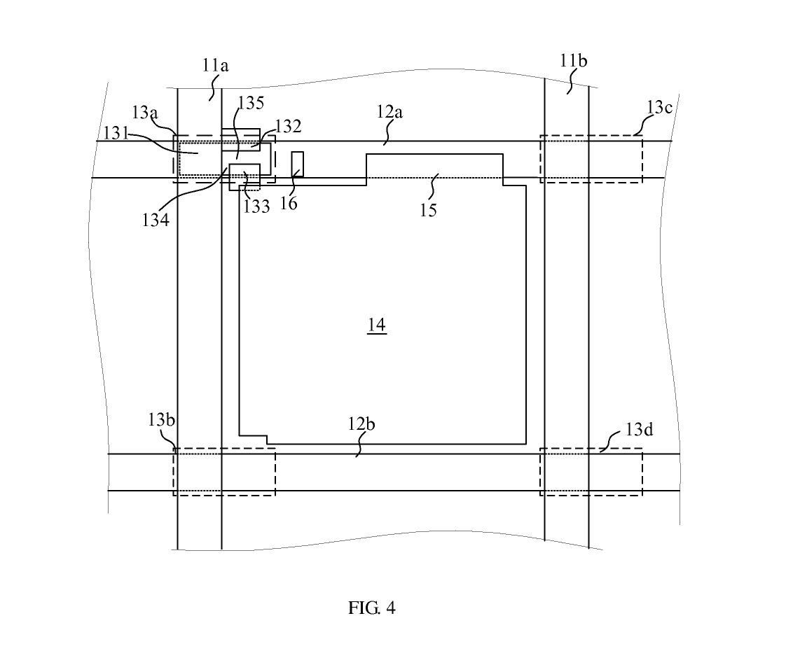

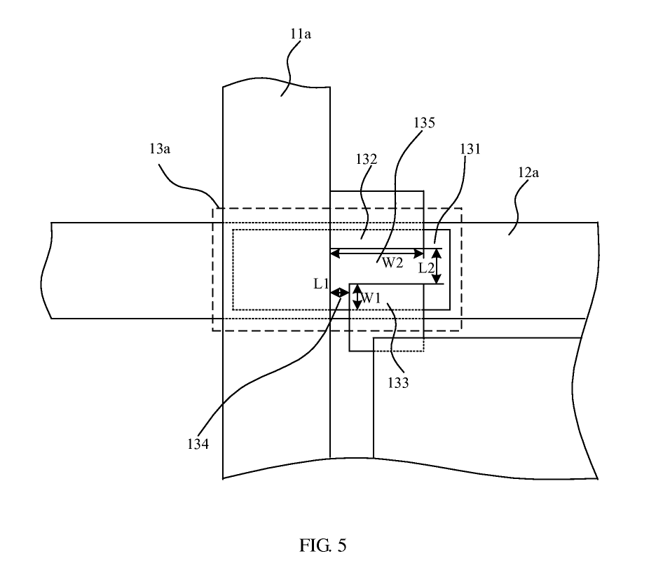

Referring to FIGS. 4 and 5, in a third embodiment, the configuration of each TFT is different from that of the first and second embodiments. For example, in the third embodiment, a first conductive channel 134 and a second conductive channel 135 are formed in each TFT. Take the TFT 13a as an example, the first conductive channel 134 is formed between the drain electrode 133 and the data line 11a, and the second conductive channel 135 is formed between the drain electrode 133 and the source electrode 132. The second conductive channel 135 communicates with the first conductive channel 134 to define an L shape.

Widthwise directions of the first and second conductive channels 134, 135 are respectively parallel to the data line 11a and the gate line 12a. In a situation where the first conductive channel 134 has a width W1 and a length L1, and the second conductive channel 135 has a width W2 and a length L2, the width/length ratio of the first conductive channel 134 can be expressed as W1/L1 and the width/length ratio of the second conductive channel 135 can be expressed as W2/L2. In this state, the length L1 of the first conductive channel 134 can be reduced so as to increase the width/length ratio of the first conductive channel 134, and the width W2 of the second conductive channel 135 can be increased so as to the increase the width/length ratio of the second conductive channel 135 to increase the charging current of the TFT 13a. Thus, the aperture ratio of the TFT array substrate can be increased without increasing the height of the gate line 12a.

In the TFT array substrate of the liquid crystal panel of the present disclosure, the TFT 13a is disposed on the junction of the data line 11a and the gate line 12a to increase the aperture ratio of the TFT array substrate without reducing the wirings of the gate line 12a and the data line 11a. Additionally, the storage capacitor 15 and the compensation capacitor 16 are all disposed on the gate line 12a, thus, the aperture ratio can be further increased.

The present disclosure further provides a liquid crystal panel having a thin film transistor (TFT) array substrate. Referring to FIGS. 1 to 3, in a first embodiment, the TFT array substrate includes a plurality of parallel data lines and a plurality of parallel gate lines. Each data line is perpendicularly and insulatingly connected to the gate lines respectively. Every two adjacent data lines and every two adjacent gate lines forms a pixel area. For example, as shown in FIG. 1, the TFT array substrate includes two adjacent data lines 11a, 11b and two adjacent gate lines 12a, 12b each which is connected to the data lines 11a, 11b respectively to form the pixel area.

The TFT array substrate further includes a pixel electrode 14 disposed in each pixel area. Four TFTs 13a, 13b, 13c, and 13d are respectively disposed in four junctions of the two data lines 11a, 11b and the two gate lines 12a, 12b. Take the TFT 13a as an example, as a switching unit of the pixel electrode 14, the TFT 13a includes a gate electrode 131 connected to the gate line 12a, a source electrode 132 connected to the data line 11a, and a drain electrode 133 connected to the pixel electrode 14. The gate electrode 131 can work as a switch of the TFT 13a. A conductive channel 130 is formed between the drain electrode 133 and the source electrode 132 with a widthwise direction thereof parallel to the data line 11a.

The pixel electrode 14 is partly overlapped with the gate line 12a to define a storage capacitor 15. A compensation capacitor 16 is disposed on the gate line 12a to compensate a parasitic capacitance generated between the data line 11a and the gate line 12a. When the TFT 13a is turned on, the storage capacitor 15 is charged to store a voltage for maintaining the gray scale voltage applied to the pixel electrode 14 when the TFT 13a is turned off. In this way, the gray scale voltage can be kept being applied to the pixel electrode 14 until the TFT 13a is turned on again to ensure the continuous display of the images. The value of the parasitic capacitance may be changed in different TFT array substrates due to different tolerances. In this state, the, compensation capacitor 16 can compensate the parasitic capacitance to allow the total capacitance value of the storage capacitor 15 and the compensation capacitor 16 to reach a stable value. Thus, the compensation capacitor 16 can improve the electrical property of the TFT 13a. Additionally, since the storage capacitor 15 and the compensation capacitor 16 are all disposed on the gate line 12a, therefore, an aperture ratio of the TFT substrate is increased.

Referring to FIGS. 4 and 5, in a second embodiment, the configuration of each TFT is different from that of the first and second embodiments. For example, in the third embodiment, a first conductive channel 134 and a second conductive channel 135 are formed in each TFT. Take the TFT 13a as an example, the first conductive channel 134 is formed between the drain electrode 133 and the data line 11a, and the second conductive channel 135 is formed between the drain electrode 133 and the source electrode 132. The second conductive channel 135 communicates with the first conductive channel 134 to define an L shape.

In the TFT array substrate of the liquid crystal panel of the present disclosure, the TFT 13a is disposed on the junction of the data line 11a and the gate line 12a so as to increase the aperture ratio of the TFT array substrate without reducing the number of wiring of the gate lines and the data lines. Additionally, the storage capacitor 15 and the compensation capacitor 16 are all disposed on the gate line 12a, thus, the aperture ratio can be further increased.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A thin film transistor array substrate of a liquid crystal display, comprising:
a plurality of data lines;
a plurality of gate lines insulatingly intersecting with the data lines respectively;
a plurality of pixel areas defined by the data lines and scan lines, wherein each pixel area including:
a pixel electrode disposed in each pixel area;
a storage capacitor disposed on the gate line; and
a thin film transistor disposed on the junction of the data line and the gate line, and width of a part of each gate line corresponding to the thin film transistor being larger than that of the other part thereof, each thin film transistor comprising:
a gate electrode connected to the corresponding gate line;
a source electrode connected to the corresponding data line;
a drain electrode connected to the pixel electrode; and
a first conductive channel and a second conductive channel being formed between the source electrode and the drain electrode, widthwise directions of the first conductive channel and the second conductive channel being respectively parallel to the corresponding data line and the corresponding gate line, and the second conductive channel communicating with the first conductive channel to define an L shape.

2. The thin film transistor array substrate as claimed in claim 1, wherein the pixel area further comprises a compensation capacitor disposed on each gate line for compensating a parasitic capacitance generated on the junction of the data line and the gate line.

3. A thin film transistor array substrate, comprising:
a plurality of data lines;
a plurality of gate lines insulatingly intersecting with the data lines respectively;
a plurality of pixel areas defined by the data lines and scan lines, wherein each pixel area including:
a pixel electrode disposed in each pixel area;
a thin film transistor disposed on the junction of the data line and the gate line; and
a storage capacitor disposed on each gate line.

4. The thin film transistor array substrate as claimed in claim 3, wherein the pixel area further comprises a compensation capacitor disposed on each gate line for compensating a parasitic capacitance generated on the junction of the data line and the gate line.

5. The thin film transistor array substrate as claimed in claim 4, wherein the compensation capacitor and the storage capacitor are disposed on the gate line between two adjacent thin film transistors.

6. The thin film transistor array substrate as claimed in claim 4, wherein the thin film transistor comprises a gate electrode connected to the corresponding gate line, a source electrode connected to the corresponding data line, and a drain electrode connected to the pixel electrode, a conductive channel is formed between the source electrode and the drain electrode and widthwise direction of the conductive channel is parallel to the corresponding data line.

7. The thin film transistor array substrate as claimed in claim 6, wherein width of a part of each gate line corresponding to the thin film transistor is larger than that of the other part thereof.

8. The thin film transistor array substrate as claimed in claim 3, wherein each thin film transistor comprises a gate electrode connected to the corresponding gate line, a source electrode connected to the data line, and a drain electrode connected to the pixel electrode, a conductive channel is formed between the source electrode and the drain electrode with widthwise direction thereof parallel to the corresponding data line.

9. The thin film transistor array substrate as claimed in claim 8, wherein width of a part of each gate line corresponding to the thin film transistor is larger than that of the other part thereof.

10. The thin film transistor array substrate as claimed in claim 4, wherein each thin film transistor comprises a gate electrode connected to the corresponding gate line, a source electrode connected to the corresponding data line, and a drain electrode connected to the pixel electrode, a first conductive channel and a second conductive channel are formed between the source electrode and the drain electrode, widthwise directions of the first conductive channel and the second conductive channel are respectively parallel to the corresponding data line and the corresponding gate line, and the second conductive channel communicates with the first conductive channel to define an L shape.

11. The thin film transistor array substrate as claimed in claim 3, wherein each thin film transistor comprises a gate electrode connected to the corresponding gate line, a source electrode connected to the corresponding data line, and a drain electrode connected to the pixel electrode, a first conductive channel and a second conductive channel are formed between the source electrode and the drain electrode, widthwise directions of the first conductive channel and the second conductive channel are respectively parallel to the corresponding data line and the corresponding gate line, and the second conductive channel communicates with the first conductive channel to define an L shape.

12. A liquid crystal panel, comprising:
a thin film transistor array substrate, comprising:
a plurality of data lines;
a plurality of gate lines insulatingly intersecting with the data lines respectively;
a plurality of pixel areas defined by the data lines and scan lines, wherein each pixel area including:
a pixel electrode disposed in each pixel area;
a thin film transistor disposed on the junction of the data line and the gate line; and
a storage capacitor disposed on each gate line of each pixel area.

13. The liquid crystal panel as claimed in claim 12, wherein the pixel area further comprises a compensation capacitor disposed on each gate line for compensating a parasitic capacitance generated on the junction of the data line and the gate line.

14. The liquid crystal panel as claimed in claim 13, wherein the compensation capacitor and the one storage capacitor are disposed on the corresponding gate line between two adjacent thin film transistors.

15. The liquid crystal panel as claimed in claim 13, wherein each thin film transistor comprises a gate electrode connected to the corresponding gate line, a source electrode connected to the corresponding data line, and a drain electrode connected to the pixel electrode, a conductive channel is formed between the source electrode and the drain electrode and widthwise direction of the conductive channel is parallel to the corresponding data line.

16. The liquid crystal panel as claimed in claim 15, wherein width of a part of each gate line corresponding to the thin film transistor is larger than that of the other part thereof.

17. The liquid crystal panel as claimed in claim 12, wherein the thin film transistor comprises a gate electrode connected to the corresponding gate line, a source electrode connected to the corresponding data line, and a drain electrode connected to the pixel electrode, a conductive channel is formed between the source electrode and the drain electrode and widthwise direction of the conductive channel is parallel to the corresponding data line.

18. The liquid crystal panel as claimed in claim 17, wherein a width of a part of the gate line of each pixel area corresponding to the thin film transistor is larger than that of other part thereof.

19. The liquid crystal panel as claimed in claim 13, wherein each thin film transistor comprises a gate electrode connected to the corresponding gate line, a source electrode connected to the corresponding data line, and a drain electrode connected to the pixel electrode, a first conductive channel and a second conductive channel are formed between the source electrode and the drain electrode, widthwise directions of the first conductive channel and the second conductive channel are respectively parallel to the corresponding data line and the corresponding gate line, and the second conductive channel communicates with the first conductive channel to define an L shape.

20. The liquid crystal panel as claimed in claim 12, wherein each thin film transistor comprises a gate electrode connected to the corresponding gate line, a source electrode connected to the corresponding data line, and a drain electrode connected to the pixel electrode, a first conductive channel and a second conductive channel are formed between the source electrode and the drain electrode, widthwise directions of the first conductive channel and the second conductive channel are respectively parallel to the corresponding data line and the corresponding gate line, and the second conductive channel communicates with the first conductive channel to define an L shape.
